(19) United States
(12) Patent Application Publication
(10) Pub. No.: US 2014/0054754 A1
(43) Pub. Date: Feb. 27, 2014

(54) OPTICALLY REACTIVE MASKING

(71) Applicants: Tadayoshi Watanabe, Fishkill, NY (US); Hideaki Masuda, White Plains, NY (US); Hideshi Miyajima, Clifton Park, NY (US)

(72) Inventors: Tadayoshi Watanabe, Fishkill, NY (US); Hideaki Masuda, White Plains, NY (US); Hideshi Miyajima, Clifton Park, NY (US)

(73) Assignee: TOSHIBA AMERICA ELECTRONIC COMPONENTS, INC., Irvine, CA (US)

(21) Appl. No.: 13/590,341

(22) Filed: Aug. 21, 2012

(51) Int. Cl. H01L 21/768; H01L 29/02

(52) U.S. Cl. 257/635; 438/675; 257/E21.586; 257/E29.002

(57) ABSTRACT

Systems and methods are presented for filling an opening with material of a high integrity. A material having properties in a first physical state suitable for formation of a hard mask layer and in a second physical state having properties facilitating removal of the former hard mask layer is utilized. Utilizing the material as a mask layer and subsequently removing the material enables a number of mask layers to be minimized in a subsequent filling operation (e.g., metallization). Material amenable to being in a first physical state and a second physical state is an optically reactive material. The optically reactive dielectric can comprise an element or compound which can act as an agent/catalyst in the optical conversion process along with any element or compound which can act as an accelerator for the optical reaction. Conversion can be brought about by exposure to electromagnetic radiation and/or application of thermal energy.

### FIELD

Embodiments described herein relate generally to methods and systems for improved filling of structures (e.g., conductive pathways, isolators, etc.) in semiconductor devices.

### BACKGROUND

Silicon large-scale integrated circuits, among other device technologies, are applied ubiquitously throughout modern society to accommodate the needs for digital information and digital control. An integrated circuit may comprise a plurality of semiconductor devices, such as transistors or the like, which can be produced according to a variety of techniques. To facilitate increased integration and speed of semiconductor devices, a trend of continuously scaling semiconductors (e.g., reducing size and features of semiconductor devices) has emerged. Reducing semiconductor and/or semiconductor feature size provides improved speed, performance, density, cost per unit, etc., of resultant integrated circuits. However, as semiconductor devices and device features have become smaller, conventional fabrication techniques have become limited in their ability to produce finely defined features.

Conventionally, front-end-of-line (FEOL) fabrication processing of an integrated circuit relates to patterning of devices (e.g., transistors, capacitors, resistors, etc.) in the semiconductor. Formation of interconnects to facilitate connection of the various devices conventionally occurs during back-end-of-line (BEOL) fabrication. By way of example, interconnects are formed during BEOL fabrication of an integrated circuit structure to facilitate connection between conductive patterns comprising conductive lines separated by interwiring spacings, and a plurality of interconnect lines, such as bus lines, bit lines, word lines and logic interconnect lines comprising an integrated circuit structure. A particular aspect in interconnect formation is a via, where a via can be formed in an insulator, dielectric, or similar structure, and facilitates connection between the various conductive elements comprising the integrated circuit structure. However, owing to the number of operations required to form the via, and associated structures, processing conflicts can occur whereby an operation required to create/modify one structure can have a deleterious effect on a nearby structure.

FIG. 15 illustrates a conventional approach for construction of an opening (e.g., a trench, via, or combination thereof). A semiconductor stack is depicted following formation of at least one opening 570, 580, and 590, where an opening can be formed by any suitable technique such as, for example, reactive ion etch (RIE). The semiconductor stack comprises a first interlayer dielectric layer 510, on which are formed a capping layer 520, a second interlayer dielectric 530, a first hard mask layer 540, a second hard mask layer 550, and a third hard mask layer 560. In a conventional semiconductor stack, the first hard mask layer 540, for example, comprises SiOC with a thickness of about 20-30 nm, the second hard mask layer 550, for example, comprises SiO₂ with a thickness of about 20-30 nm, and a third hard mask layer 560, for example, is a metal layer (e.g., TIN) with a thickness of about 10-20 nm.

FIG. 16 illustrates a final cleaning operation where owing to etch selectivity, first hard mask layer 540 has been preferentially removed relative to the second hard mask layer 550. Tapering of the side walls of the opening can result in the first hard mask layer 540 being removed such that an undercut (as indicated) is formed under the second hard mask layer 550. The final cleaning operation can result in removal of material from the interlayer dielectric 530 and the first hard mask layer 540 as indicated by the broken lines.

FIG. 17 illustrates filling of openings 570, 580, and 590, where as indicated in the enlarged image, impartial filling of the openings results in voids being formed in the undercut regions of FIG. 16. As illustrated, during subsequent formation of a connector (e.g., during metallization of openings 570, 580, 590) it may not be possible to fill the undercut regions and thus connectors are formed with voids occurring at the undercut, which can lead to impaired operation of the connector compared to that anticipated.

A further concern is the lack of removal of any of the hard mask layers (e.g., any of first hard mask layer 540, second hard mask layer 550, or third hard mask layer 560) prior to the metallization process and thus the aspect ratio of any of the openings 570, 580 or 590 is high (e.g., the depth of an opening is high compared to the width), which can also lead to poor formation of a connector during filling (e.g., metallization), as indicated by partially filled region 598 in the exploded view FIG. 17.

Hence, while technologies facilitate further miniaturization of semiconductor related devices and components, issues regarding construction of the trenches, vias and subsequently formed structures are still to be addressed.

### SUMMARY

A simplified summary is provided herein to help enable a basic or general understanding of various aspects of exemplary, non-limiting embodiments that follow in the more detailed description and the accompanying drawings. This summary is not intended, however, as an extensive or exhaustive overview. Instead, the sole purpose of this summary is to present some concepts related to some exemplary non-limiting embodiments in a simplified form as a prelude to the more detailed description of the various embodiments that follow.

The subject innovation presents various techniques related to filling openings (e.g., in a metallization process), etc., having a high integrity compared with structures formed by a conventional approach(es). A material having properties in a first physical state suitable for formation of a hard mask layer and in a second physical state having properties facilitating removal of the former hard mask layer are applicable to the various embodiments presented herein. By utilizing the material as a mask layer and subsequently being able to remove the material enables the number of mask layers to be minimized in a subsequent filling operation (e.g., metallization) as well as preventing the formation of voids from mask layer undercutting, thereby enabling a structure (e.g., a connector, isolator) to be formed with high structural integrity, homogeneity.

In an exemplary, non-limiting embodiment, the material amenable to being in a first physical state and a second physical state is an optically reactive material, e.g., an optically reactive dielectric or optical dielectric. In an exemplary, non-limiting embodiment, the optically reactive dielectric can further comprise an element/compound which can act as an agent/catalyst in the optical conversion process along with any element/compound which can act as an accelerator for the optical reaction. Conversion from the first physical state to the second physical state can occur by exposing the material to electromagnetic radiation, such as ultraviolet light. Conversion can also be brought about by application of thermal energy, such as an annealing process.

The first physical state of the material has a high etching selectivity (hence applicability to being utilized as a mask) while the second physical state has low etching selectivity and thus can be removed by a wet etchant. Hence the material can be used as a mask to facilitate an opening being formed in a semiconductor structure, but removed prior to a filling operation (i.e., a metallization process to fill the opening) thereby reducing the aspect ratio of the opening to be filled as well as preventing void formation during filling of an undercut region.

### BRIEF DESCRIPTION OF THE DRAWINGS

FIG. 1 is a block diagram illustrating a non-limiting, exemplary embodiment of a structure comprising an optically reactive material.

FIG. 2 is a block diagram illustrating a non-limiting, exemplary embodiment of a structure comprising an optically reactive material.

FIG. 3 is a block diagram illustrating a non-limiting, exemplary embodiment of a structure comprising an optically reactive material undergoing conversion.

FIG. 4 is a block diagram illustrating a non-limiting, exemplary embodiment of the optically reactive material being removed from a structure.

FIG. 5 is a block diagram illustrating a non-limiting, exemplary embodiment of a structure undergoing filling.

FIG. 6 is a block diagram illustrating a non-limiting, exemplary embodiment of a structure undergoing planarization.

FIG. 7 illustrates a flow for forming a conductive element in a structure by utilizing an optically reactive material in accordance with one or more embodiments of the subject innovation.

FIG. 8 is a block diagram illustrating a non-limiting, exemplary embodiment of a structure comprising an optically reactive material.

FIG. 9 is a block diagram illustrating a non-limiting, exemplary embodiment of a structure comprising an optically reactive material.

FIG. 10 is a block diagram illustrating a non-limiting, exemplary embodiment of a structure comprising an optically reactive material undergoing conversion.

FIG. 11 is a block diagram illustrating a non-limiting, exemplary embodiment of the optically reactive material being removed from a structure.

FIG. 12 is a block diagram illustrating a non-limiting, exemplary embodiment of a structure undergoing filling.

FIG. 13 is a block diagram illustrating a non-limiting, exemplary embodiment of a structure undergoing planarization.

FIG. 14 illustrates a flow for forming a conductive element in a structure by utilizing an optically reactive material in accordance with one or more embodiments of the subject innovation.

FIG. 15 illustrates a structure comprising a plurality of hard mask layers and openings.

FIG. 16 illustrates an undercut being formed in a structure comprising a plurality of hard mask layers and openings.

FIG. 17 illustrates forming a conductive element in a structure having an undercut region.

### DETAILED DESCRIPTION

The subject innovation presents various techniques relating to forming a structure with a high integrity, homogeneity. The various exemplary, non-limiting embodiments presented herein relate to reducing the number of mask layers which can affect ease of filling an opening. And further, preventing formation of an undercut beneath a hard mask layer which can have a deleterious effect on subsequent filling during metallization of a conductive pathway formed in an opening such as a trench, via, or combination thereof. As described in the background, a plurality of mask layers may be utilized to facilitate formation of an opening, where etch selectivity (e.g., during a cleaning operation) may cause a portion of an underlying mask to be removed thereby causing an undercut which can be difficult to fill without the formation of voids in the conductive pathway. As depicted in FIG. 17, owing to the inability to completely fill the trench/via during metallization an incomplete conductive pathway is formed comprising voids owing to poor metal filling.

Presented herein are embodiments whereby a material is utilized having a first physical state which enables the material to act as a mask layer, and wherein the material can be transformed to a second physical state having a different etch selectivity to the first state, thereby enabling the material in the second physical state to be removed by a removal technique (e.g., by wet etch) which is not conducive to removing the material when the material is in the first physical state.

A suitable material is an optically reactive material (e.g., an optically-reactive dielectric) where the physical/chemical properties of the optically reactive material are transformed from the first physical state to a second physical state by exposure to electromagnetic energy, such as ultraviolet (UV) light, in conjunction with any other necessary processing such as thermal processing, e.g., an annealing operation. By utilizing a optically reactive dielectric the formation of an undercut (as shown in FIG. 16) is minimized, thereby facilitating formation of structurally sound conductive pathway(s) during a subsequent filling operation, e.g., metallization. Further, while in a first physical state the optically reactive material can be utilized as a hard mask, while in a second state (i.e., after optical processing) the optically reactive material can be in a condition to facilitate removal by a wet treatment while an underlying mask remains, which reduces the number of hard mask layers. Such removal reduces the aspect ratio of an opening (e.g., height to width) thereby enabling the opening to be filled with greater ease than for a high aspect ratio opening (per the high aspect ratio opening presented in FIG. 17).

It is to be appreciated that while the various exemplary, non-limiting embodiments presented herein generally relate to formation and filling of at least one opening to form a conductive pathway (e.g., metallized structures) the various exemplary, non-limiting embodiments are not so limited and the concept of utilizing a material having a variety of physical states (or structural phases) can equally be applied to the formation of other structures such as filling the openings with non-conductive material to form isolating structures, etc.

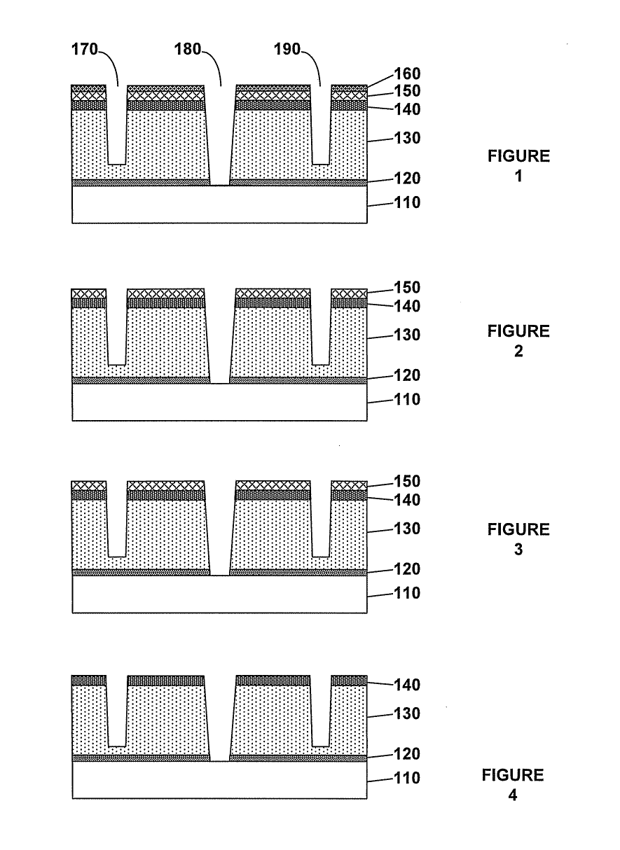

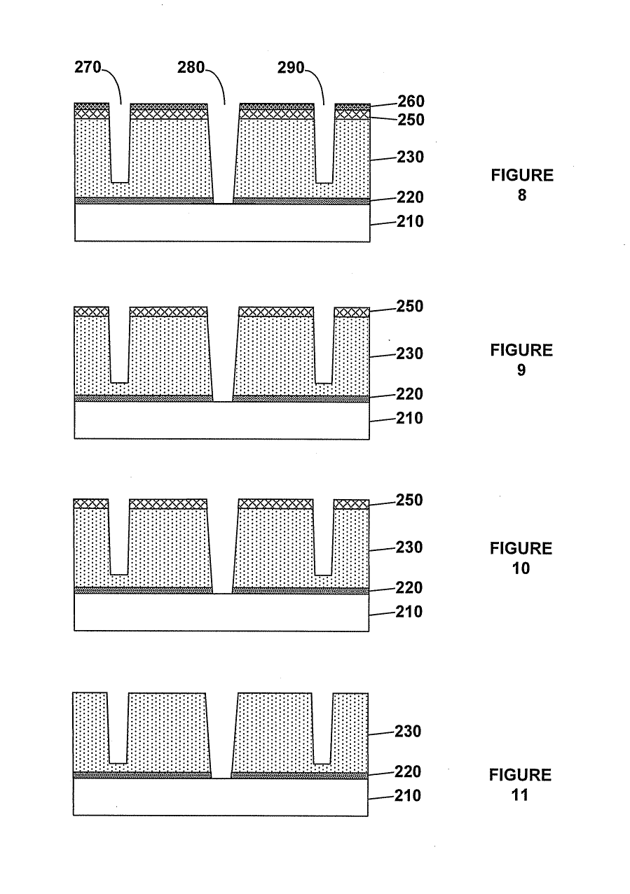

In a first exemplary, non-limiting embodiment (FIGS. 1-7), a semiconductor structure comprising three hard mask layers is presented. In a second exemplary, non-limiting embodiment (FIGS. 8-14), a semiconductor stack can be formed comprising only two hard mask layers is presented.

### Process for Semiconductor Stack Comprising Three or More Hard Mask Layers

FIGS. 1-6 illustrate a series of exemplary, non-limiting embodiments to facilitate formation of an opening (e.g., a trench/via opening) having an aspect ratio amenable to filling with a conductive material having a high integrity during metallization without undercut voids.

FIG. 1 illustrates an intermediate structure for the formation of an opening (and a subsequently formed interconnect) to connect with an underlying structure. It is to be appreciated that the various layers comprising the exemplary semiconductor stack depicted in FIGS. 1-6 (and similarly in FIGS. 8-13) are presented to facilitate understanding of the various concepts presented herein, the various concepts presented herein can be applied to any suitable semiconductor stack structure. For example, the semiconductor stack illustrated in FIGS. 1-6 (and similarly in FIGS. 8-13) can be an intermediate stage in a series of process operations, e.g., the semiconductor stack is an intermediate stage in a via formation process. The semiconductor stack comprises a first interlayer dielectric 110, a capping layer 120, a second interlayer dielectric 130, a first hard mask layer 140, a second hard mask layer 150, and a third hard mask layer 160. Owing to previous processing stages (not shown) such as patterning, lithography, etc., hard mask layers 140, 150 and 160 have been patterned to facilitate formation of openings 170, 180, and 190.

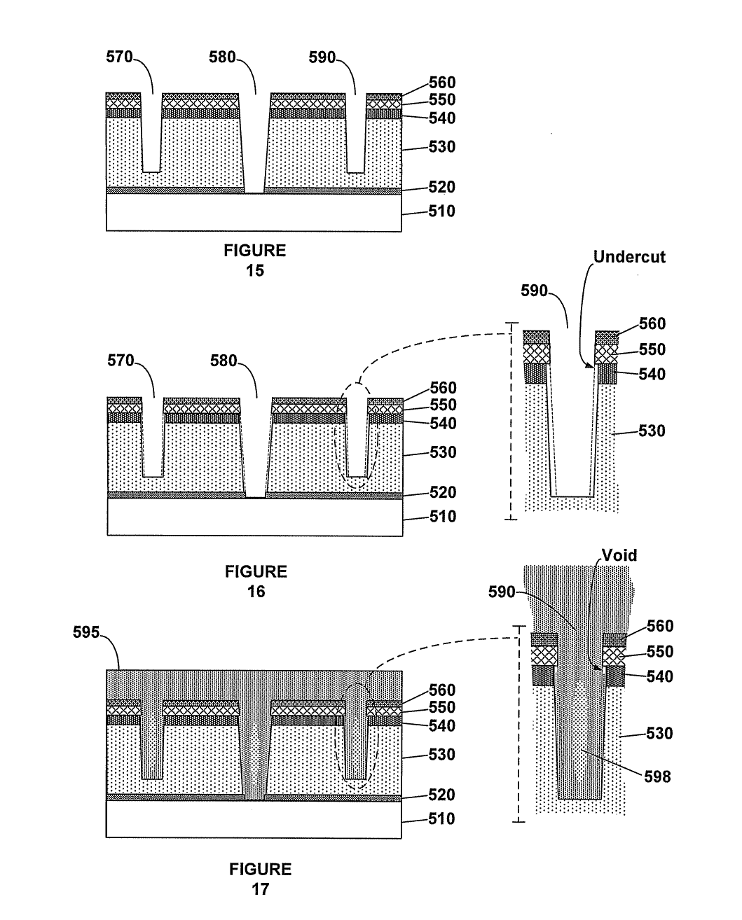

In comparison with the semiconductor stack illustrated in FIGS. 15-17, while the first hard mask layer 140 and third hard mask layer 160 may be common with the structure depicted in FIG. 15, (e.g., hard mask layers 140 and 540 are SiOC of about 20-30 nm thick, and hard mask layers 160 and 560 comprise a metal layer such as TiN of a thickness of about 10-20 nm) the second hard mask layer depicted in FIG. 15 (e.g., an SiO₂ layer) is replaced with a material having properties in one state suitable for formation of a hard mask layer and in a second state having properties facilitating removal of the former hard mask layer. A suitable material is an optically reactive material, e.g., an optically reactive dielectric or optical dielectric. In an exemplary, non-limiting embodiment, the optically reactive dielectric can further comprise an element/compound which can act as an agent/catalyst in the optical conversion process along with any element/compound which can act as an accelerator for the optical reaction. Hence, in comparison with layer 550 of FIG. 15, the base material SiO₂ layer of second hard mask layer 150 has been extended to comprise at least one element or compound to facilitate optical conversion from a first physical state to a second physical state, where the second hard mask layer 150 has a thickness of about 20-30 nm.

FIG. 2 illustrates the semiconductor stack after removal of the third hard mask layer, 160. Wherein, the third hard mask layer 160 can be removed by any suitable technique, e.g., any of a dry etch or a wet etch technique. Removal of the third hard mask layer 160 exposes the underlying second hard mask layer 150.

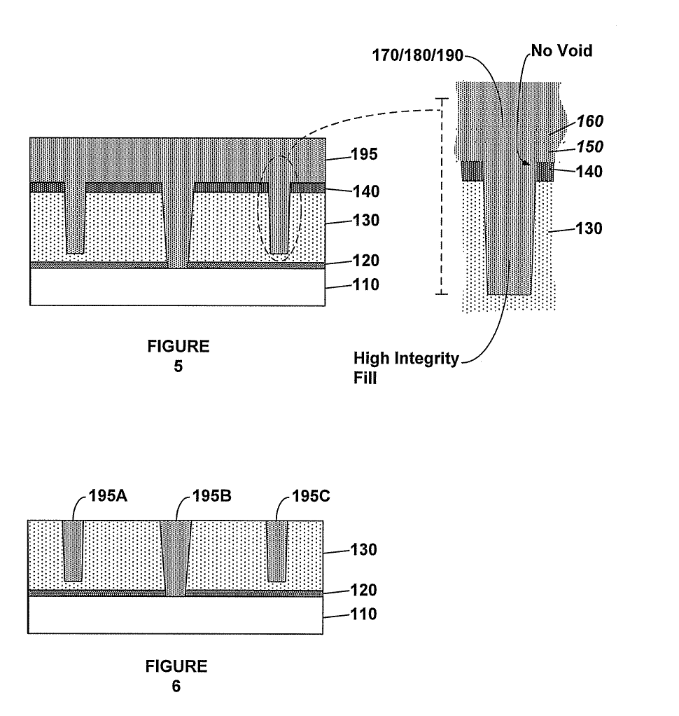

At FIG. 3, a UV treatment in conjunction with thermal processing are performed. Owing to the second hard mask layer 150 being exposed by the removal of the third hard mask layer 160, the second hard mask layer 150 can be exposed to UV light which in conjunction with a thermal process, e.g., annealing, can facilitate the conversion of the second hard mask layer 150 from a first physical state having properties suitable for employment as a hard mask to a layer of a second physical state having properties such that layer 150 can be removed by wet chemistry techniques. By enabling the second hard mask layer 150 to be in a physical state amenable to removal by a wet chemistry technique, undercutting effects (as illustrated in FIGS. 16 and 17) are negated.

FIG. 4 illustrates removal of the optically reactive layer. As shown in FIG. 4, owing to the conversion of the optically reactive layer 150 to a second physical state, removal of the optically reactive layer 150 can be by a wet etch (e.g., hydrofluoric acid) technique, a removal technique which is not amenable to removing the optically reactive layer 150 when in the first physical state. After removal of optically reactive layer 150 only the first hard mask layer 140 remains on the surface of interlayer dielectric 130.

FIG. 5 illustrates filling of the respective openings. As presented in FIG. 5, owing to only hard mask layer 140 remaining, and hard mask layer 140 being of a thickness of about 10-20 nm, the aspect ratio of openings 170, 180 and 190 to be filled is greatly reduced in comparison with the high aspect ratio openings 570, 580 and 590 (ref FIG. 16) to be filled owing to the hard mask layers 540, 550, and 560 remaining in the conventional structure depicted in FIGS. 16 and 17. Hence the ability to fill openings 170, 180 and 190 (e.g., by metallization) is greatly improved compared with filling openings 570, 580 and 590.

Furthermore, if a degree of undercutting occurs during processing of the semiconductor structure depicted in FIGS. 1-6, for example during a final cleaning operation performed after the formation of the opening by RIE (such as shown in FIG. 16), owing to the first hard mask layer 160 and second hard mask layer 150 being removed, there is no second hard mask layer 150 in place to form an undercut region and hence any of openings 170, 180, or 190 have an open profile which, in conjunction with the lower aspect ratio of the opening facilitates improved filling of the opening. As shown in the exploded view of FIG. 5, filling of any of openings 170, 180, or 190 has high integrity as the first hard mask layer 160 and second hard mask layer 150 have been removed (as indicated by the broken line and italicized numerals) thus fully exposing the opening for metallization, etc.

FIG. 6 illustrates the final semiconductor stack after chemical-mechanical planarization (CMP). As illustrated, the final structure, after removal of the first hard mask layer 140 comprises the three openings 170, 180 and 190 respectively filled with conductive material to form structures 195A, 195B, and 195C having a high structural integrity, with material 195B extending through the opening in capping layer 120 to connect with the first interlayer dielectric 110.

Hence, as illustrated in FIGS. 1-6, by utilizing an intermediate hard mask layer (e.g., layer 150) comprising a material which can be transformed from a first physical state to a second physical state, operations in forming a connector can be improved over a conventional approach.

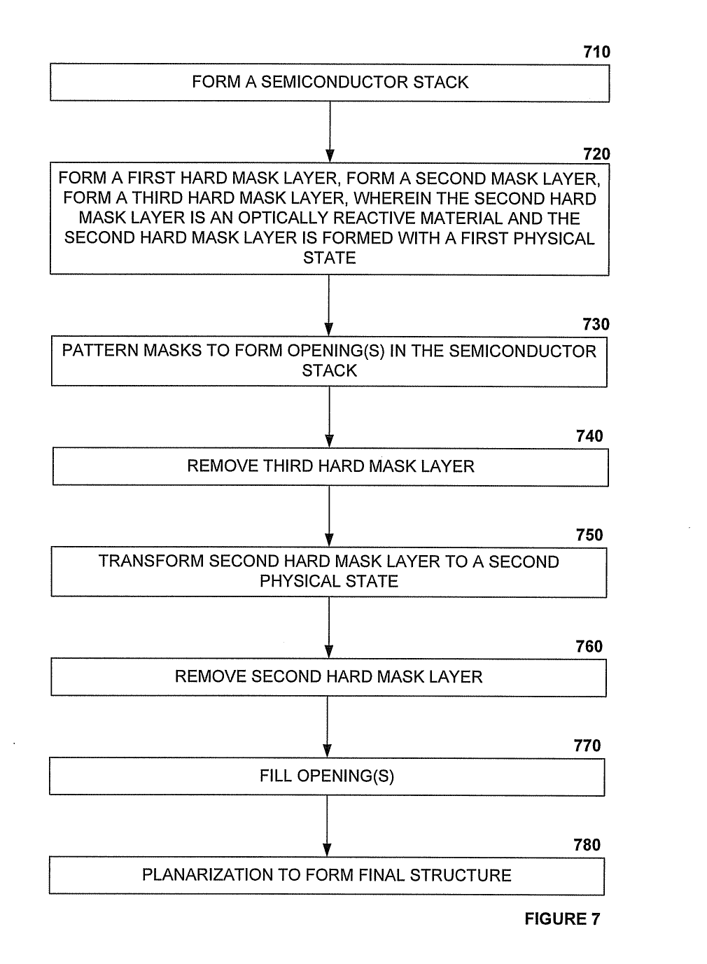

FIG. 7 presents a flow diagram illustrating an exemplary, non-limiting embodiment to facilitate formation of at least one opening by utilizing a mask layer having a plurality of physical states. As previously described, the various exemplary, non-limiting embodiments presented herein, effectively utilize a material having a first state amenable for use as a hard mask layer, and a second state which can be removed and thus facilitate metallization of an opening having a low aspect ratio.

At 710 a semiconductor stack is formed. The various embodiments presented herein are applicable to any semiconductor structure having at least one opening formed therein. In an exemplary, non-limiting embodiment, initial layers are formed comprising a first interlayer dielectric (e.g., layer 110), a capping layer (e.g., layer 120), and a second interlayer dielectric (e.g., layer 130).

At 720, a plurality of mask layers are formed on the initial semiconductor stack. A first hard mask layer (e.g., mask 140), a second hard mask layer (e.g., mask 150), and a third hard mask layer (e.g., mask 160) are formed. In an exemplary, non-limiting embodiment, the first hard mask layer comprises SiOC with a thickness of about 20-30 nm, while the third hard mask layer comprises a metal layer, such as TiN, of a thickness of about 10-20 nm. Second hard mask layer comprises an optically reactive dielectric, as previously described with reference to layer 150, where the second hard mask layer has a thickness of about 20-30 nm.

At 730, patterning (e.g., lithography) is conducted to form one or more openings in the semiconductor stack. Patterning of the first hard mask layer, second hard mask layer and third hard mask layer, can be performed by any suitable technique to facilitate generation of openings in the respective mask layer(s) to enable formation of openings (e.g., any of openings 170, 180, 190) in the second interlayer dielectric (e.g., layer 130) and the capping layer (e.g., layer 120). In an exemplary non-limiting embodiment, the depth of an opening can be controlled to facilitate removal of material from the capping layer to expose a portion of the first interlayer dielectric (e.g., layer 110), with the depth of the opening (e.g., opening 180) being extended. The opening(s) can be formed by any suitable technique such as RIE.

At 740, the third hard mask layer (e.g., layer 160) is removed. Removal of the third hard mask layer can be by any suitable technique such as, for example, any of a dry etch or a wet etch technique. Removal of the third hard mask layer exposes the underlying second hard mask layer.

At 750, a UV treatment and any necessary thermal processing are performed. Owing to exposure of the second hard mask layer by the removal of the third hard mask layer, the second hard mask layer can be exposed to UV light which in conjunction with a thermal process, e.g., annealing, facilitates the conversion of the second hard mask layer from a first physical state, having properties suitable for employment as a hard mask, to a second physical state having properties such that the second hard mask layer can be removed by wet chemistry techniques. By enabling the second hard mask layer to be in a physical state amenable to removal by a wet chemistry technique, undercutting effects are negated, as previously described with reference to FIGS. 4-6.

At 760, the second hard mask layer is removed. Owing to the conversion of the second hard mask layer (e.g., layer 150) to a second physical state, removal of the second hard mask layer can be conducted using any suitable technique, such as a wet etch (e.g., hydrofluoric acid) technique. A wet etch is not amenable for removal of the optically reactive layer when in the first physical state. After removal of optically reactive layer only the first hard mask layer remains on the surface of the second interlayer dielectric.

At 770, filling of the respective openings is performed. Owing to only the first hard mask layer remaining, and the thickness of the first hard mask layer being about 10-20 nm, the aspect ratio of the respective openings is greatly reduced (in comparison with the high aspect ratio openings 570, 580 and 590 (ref FIG. 16)) enabling filling of the respective openings with material of a high integrity (e.g., connectors 195A, 195B, 195C). Hence, the ability to fill the respective openings is greatly improved compared with filling openings (e.g., opening 570, 580 and 590) of a conventional approach.

Furthermore, if a degree of undercutting occurs during processing of the semiconductor structure, for example during a final cleaning operation performed after the formation of an opening by RIE, owing to the first hard mask layer and second hard mask layer being removed, there is no second hard mask layer present to form an undercut region and hence the openings have an open profile (ref FIG. 5), which in conjunction with the lower aspect ratio of the opening, facilitates improved filling of the opening, e.g., during metallization.

At 780, planarization (e.g., by chemical-mechanical planarization (CMP)) is performed to achieve the final required structure of at least one connector, wherein the connector has a high integrity. During planarization, the first hard mask layer is removed, with the planarized connector, having a high integrity, extending into at least the second interlayer dielectric, and if required into the capping layer (e.g., layer 120) to connect with the underlying first interlayer dielectric (e.g., layer 110).

### Process for Semiconductor Stack Comprising Two or More Hard Mask Layers

FIGS. 8-13 illustrate a series of exemplary, non-limiting embodiments to facilitate formation of an opening (e.g., a trench/via opening) having an aspect ratio amenable to filling with a conductive material having a high integrity during metallization without undercut voids. In the exemplary, non-limiting embodiment presented in FIGS. 8-13, a semiconductor stack is be formed comprising only two hard mask layers.

FIG. 8 illustrates an intermediate structure for the formation of an opening (and a subsequently formed interconnect) to connect with an underlying structure. It is to be appreciated that the various layers comprising the exemplary semiconductor stack depicted in FIGS. 8-13 are presented to facilitate understanding of the various concepts presented herein, while the various concepts presented herein can be applied to any suitable semiconductor stack structure. For example, the semiconductor stack illustrated in FIGS. 8-13 can be an intermediate stage in process operations such that the semiconductor stack is an intermediate stage in a via formation process. The semiconductor stack comprises a first interlayer dielectric 210, a capping layer 220, a second interlayer dielectric 230, a first hard mask layer 250, and a second hard mask layer 260. Owing to previous processing stages (not shown) such as patterning, lithography, etc., hard mask layers 250 and 260 have been patterned to facilitate formation of openings 270, 280, and 290.

The second hard mask layer 260 can comprise TIN with a thickness of about 10-20 nm. The first hard mask layer 250 comprises an optical reactive material, as previously described (e.g., with reference to FIGS. 1-6, layer 150) with a thickness of about 20-30 nm.

FIG. 9 illustrates the semiconductor stack after removal of the second hard mask layer 260. Wherein, the second hard mask layer 260 can be removed by any suitable technique, e.g., any of a dry etch or a wet etch technique. Removal of the second hard mask layer 260 exposes the underlying first hard mask layer 250.

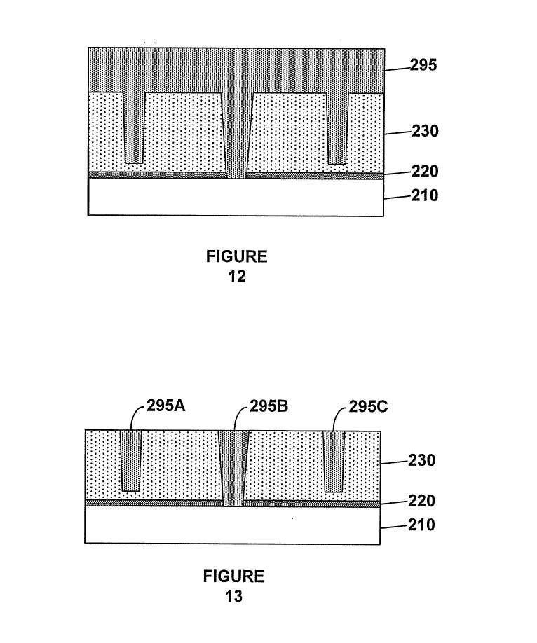

At FIG. 10, a UV treatment in conjunction with a thermal process, e.g., an annealing process, are performed. Owing to the first hard mask layer 250 being exposed by the removal of the second hard mask layer 260, the first hard mask layer 250 can be exposed to UV light which in conjunction with a thermal process can facilitate the conversion of the first hard mask layer 250 from a first physical state having properties suitable for employment as a hard mask to a layer of a second physical state having properties such that layer 250 can be removed by wet chemistry techniques.

FIG. 11 illustrates removal of the optically reactive layer. As shown in FIG. 11, owing to the conversion of the optically reactive layer 250 to a second physical state, removal of the optically reactive layer 250 can be by a wet etch (e.g., hydrofluoric acid) technique, a removal technique which is not amenable for removal of the optically reactive layer 250 when in the first physical state. After removal of optically reactive layer 250 the surface of interlayer dielectric 230 is exposed for metallization.

FIG. 12 illustrates filling of the respective openings. As presented in FIG. 12, owing to no hard mask layers remaining on the surface of interlayer dielectric 230, the aspect ratio of openings 270, 280 and 290 to be filled is greatly reduced in comparison with the high aspect ratio openings 570, 580 and 590 (ref FIG. 16) to be filled owing to the hard mask layers 540, 550, and 560 remaining in the conventional structure depicted in FIGS. 16 and 17. Hence the ability to fill openings 270, 280 and 290 is greatly improved compared with filling openings 570, 580 and 590.

FIG. 13 illustrates the final semiconductor stack after chemical-mechanical planarization (CMP). As illustrated, the final structure comprises the three openings 270, 280 and 290 respectively filled with structures 295A, 295B, and 295C having a high structural integrity, with material 295B extending through the opening in capping layer 220 to connect with the first interlayer dielectric 210.

Hence, as illustrated in FIGS. 8-13, by utilizing a hard mask layer (e.g., layer 250) comprising a material which can be transformed from a first physical state to a second physical state, operations for filling an opening can be improved over a conventional approach.

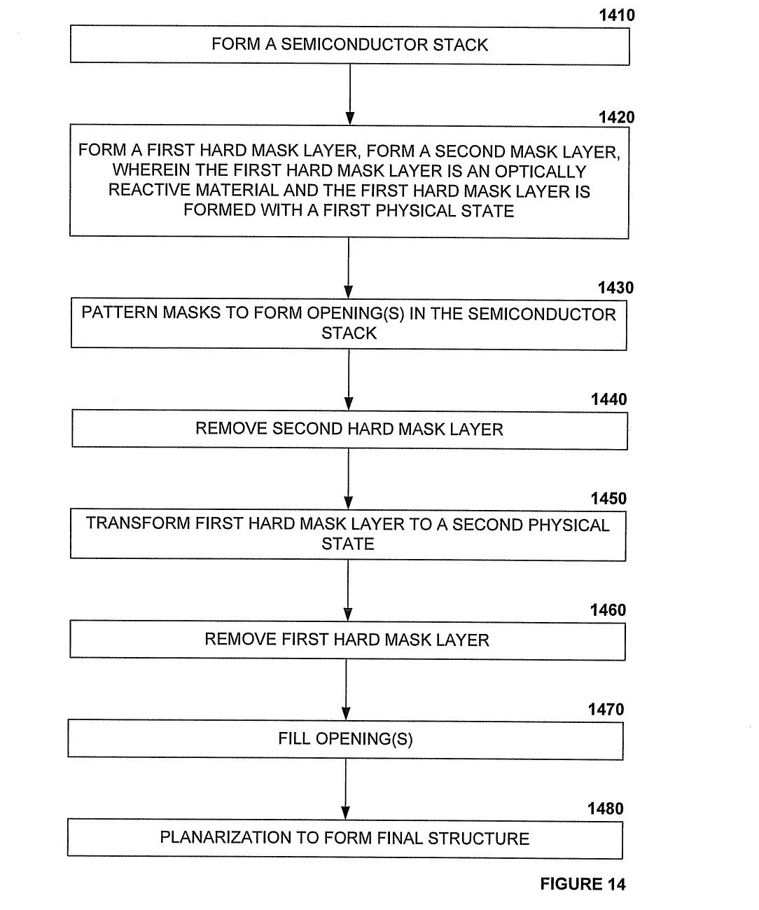

FIG. 14 presents a flow diagram illustrating an exemplary, non-limiting embodiment to facilitate formation of at least one opening by utilizing a mask layer having a plurality of physical states. As previously described, the various exemplary, non-limiting embodiments presented herein, effectively utilize a material having a first state amenable for use as a hard mask layer, and a second state which can be removed and thus facilitate filling of an opening having a low aspect ratio.

At 1410 a semiconductor stack is formed. The various embodiments presented herein are applicable to any semiconductor structure having at least one opening formed therein. In an exemplary, non-limiting embodiment, initial layers are formed comprising a first interlayer dielectric (e.g., layer 210), a capping layer (e.g., layer 220), and a second interlayer dielectric (e.g., layer 230).

At 1420, a plurality of mask layers are formed on the initial semiconductor stack. A first hard mask layer (e.g., mask 250) and a second hard mask layer (e.g., mask 260) are formed. In an exemplary, non-limiting embodiment, the second hard mask layer comprises a metal layer, such as TiN, of a thickness of about 10-20 nm. The first hard mask layer comprises an optically reactive dielectric or optical dielectric as previously described with reference to layer 250, the first hard mask layer has a thickness of about 20-30 nm.

At 1430, patterning (e.g., lithography) is conducted to form one or more openings in the semiconductor stack. Patterning of the first hard mask layer and second hard mask layer can be performed by any suitable technique to facilitate generation of openings in the respective mask layer(s) to enable formation of openings (e.g., any of openings 270, 280, 290) in the second interlayer dielectric (e.g., layer 230) and the capping layer (e.g., layer 220). In an exemplary non-limiting embodiment, the depth of an opening can be controlled to facilitate removal of material from the capping layer to expose a portion of the first interlayer dielectric (e.g., layer 210), with the depth of the opening (e.g., opening 280) being extended. The opening(s) can be formed by any suitable technique such as RIE.

At 1440, the second hard mask layer (e.g., layer 260) is removed. Removal of the second hard mask layer can be by any suitable technique such as, for example, any of a dry etch or a wet etch technique. Removal of the second hard mask layer 260 exposes the underlying second hard mask layer.

At 1450, a UV treatment and thermal processing are performed. Owing to exposure of the first hard mask layer by the removal of the second hard mask layer. The first hard mask layer can be exposed to UV light which in conjunction with a thermal process facilitates the conversion of the first hard mask layer from a first physical state, having properties suitable for employment as a hard mask, to a second physical state having properties such that the first hard mask layer can be removed by wet chemistry techniques.

At 1460, the first hard mask layer is removed. Owing to the conversion of the first hard mask layer (e.g., an optically reactive layer, layer 250) to a second physical state, removal of the first hard mask layer can be conducted using any suitable technique, such as a wet etch (e.g., hydrofluoric acid) technique. A wet etch is not amenable for removal of the optically reactive layer when in the first physical state.

At 1470, filling of the respective opening(s) is performed. A layer of conductive material (e.g., layer 295) is deposited on to the second dielectric layer. Owing to no hard mask layer remaining the aspect ratio of the respective openings is greatly reduced (in comparison with the high aspect ratio openings 570, 580 and 590 (ref FIG. 16)) enabling filling of the respective openings with material of a high integrity (e.g., connectors 295A, 295B, 295C). Hence, the ability to fill the respective openings is greatly improved compared with filling openings (e.g., opening 570, 580 and 590) of a conventional approach.

At 1480, planarization (e.g., by chemical-mechanical planarization (CMP)) is performed to achieve the final required structure of at least one connector, wherein the connector has a high integrity. During planarization any unwanted material comprising the conductive layer (e.g., layer 295) is removed, with the planarized connector, having a high integrity, extending into at least the second interlayer dielectric, and if required into the capping layer (e.g., layer 220) to connect with the underlying first interlayer dielectric (e.g., layer 210).

### General Considerations

It is to be appreciated that the various layers, etc., comprising any of the semiconductor stacks presented herein are simply presented to facilitate understanding of the various exemplary, non-limiting embodiments, and application of the exemplary, non-limiting embodiments is not limited to application with semiconductor stacks comprising layers presented herein, but rather can be utilized with any semiconductor stack configuration applicable to the exemplary, non-limiting embodiments.

In brief, the various presented layers comprise of the following. The first interlayer dielectric (e.g., layer 110, 210, 510) and second interlayer dielectric (e.g., layer 130, 230, 530) can comprise of any suitable material, such as a low dielectric layer, an ultra-low dielectric layer (ULK), etc., where a material having a lower k value than SiO₂ can be utilized to prevent intra- and inter-layer capacitance, a suitable material being SiCOH or an organic material, for example. The capping layer (e.g., 120, 220, 520) can be present to facilitate isolation of the first interlayer dielectric from the second interlayer dielectric.

Hard mask layers (e.g., 140, 540; 150, 250, 550; 160, 260, 560) can be patterned to facilitate control of the shape/extent of the formed trench/via (e.g., 170, 270, 570, 180, 280, 580, 190, 290, 590). While hard mask layers 160, 260, and 560 are presented in the previous discussion as comprising of titanium nitride (TiN), any other suitable hard mask material such as TaN, silicon dioxide, silicon nitride, silicon oxynitride, boronitride, silicon boronitride, silicon carbide, and the like, can be utilized, and formed by any suitable technique such as chemical vapor deposition (CVD) or spin-on methodology.

The various layers presented above can be formed/deposited by any suitable process such as a spin coating, deposition, CVD process, for example, low pressure chemical vapor deposition (LPCVD), plasma enhanced chemical vapor deposition (PECVD), etc.

Any suitable technique can be used to pattern any of the material layers presented herein. For example, patterning can be created by employing a photoresist which is patterned using standard photolithographic techniques to form the required pattern to create the pattern, trenches, openings, etc., wherein the photoresist is exposed to electromagnetic radiation through a mask having an image pattern of a desired layout (e.g., desired trenches, openings, line patterning, etc.).

Etching can be by any etching/material removal technique that is applicable to the various embodiments, as described herein. For example, a wet or dry etching technique can be employed for patterning, while in another aspect, etching can be by a specific anisotropically etch. Etching can be utilized to remove a particular layer where a given layer may be susceptible to etch by a particular etchant while a neighboring layer is not. In another example, anisotropic etching techniques can be utilized to control material removal in a specific direction (unlike standard wet etching) such as vertically down into a stack to form an opening, etc.

Levelling of layers after formation can be by any suitable technique, e.g., by chemical mechanical polish/planarization (CMP) or other suitable process, to achieve a given dimension, in preparation for the next stage in creation of the replacement gate/contact structure, etc.

It is to be appreciated that while an optically reactive layer is utilized in the formation of an opening(s) to be subsequently filled with conductive or non-conductive material is described, there may be certain procedures that are not fully disclosed during description of the various embodiments as presented herein. However, rather than provide description of each and every operation involved in the various operations facilitating formation, patterning, removal, etc., of each structure presented herein, for the sake of description only the general operations are described. Hence, while no mention may be presented regarding a particular operation pertaining to aspects of a particular figure, it is to be appreciated that any necessary operation, while either not fully disclosed, or not mentioned, to facilitate formation/deconstruction of a particular layer/element/aspect presented in a particular figure is considered to have been conducted. For example, while no mention may be made regarding a layer described in a preceding figure being leveled (e.g., by chemical mechanical polish, or other suitable operation) it is considered, for the sake of readability of the various exemplary embodiments presented herein, that the leveling process occurred, as have any other necessary operations. It is appreciated that the various operations, e.g., leveling, chemical mechanical polish, patterning, photolithography, deposition, layer formation, etching, etc., are well known procedures and are not necessarily expanded upon throughout this description.

The claimed subject matter has been described with reference to the drawings, wherein like reference numerals are used to refer to like elements throughout. In the description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

It is to be appreciated that the various Figures illustrating the various embodiments presented herein are simply rendered to facilitate understanding of the various embodiments. Accordingly, the various embodiments can be applicable to respective elements of any dimension, scaling, area, volume, distance, etc., and while a Figure may illustrate a dimension of one element rendered in association with another element, the respective dimensions, scaling, ratios, etc., are not limited to those as rendered but can be of any applicable magnitude.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim. The word “exemplary” is used herein to mean serving as an example, instance, or illustration. For the avoidance of doubt, the subject matter disclosed herein is not limited by such examples. In addition, any aspect or design described herein as “exemplary” is not necessarily to be construed as preferred or advantageous over other aspects or designs, nor is it meant to preclude equivalent exemplary structures and techniques known to those of ordinary skill in the art.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

What is claimed is:

1. A method for forming a semiconductor device, comprising:
forming a semiconductor stack comprising a plurality of layers including a first mask layer, a second mask layer formed on the first mask layer, and a third mask layer formed on the second mask layer, wherein the second mask layer comprising an optically reactive layer in a first physical state;
patterning the first mask layer, the second mask layer, and the third mask layer facilitating forming an opening in the semiconductor stack;
removing the third mask layer exposing the second mask layer in the first physical state; and
converting the second mask layer to a second physical state.

2. The method of claim 1, further comprising removing the second mask layer in the second physical state.

3. The method of claim 2, wherein the removing of the second mask layer in the second physical state being by a wet etch technique.

4. The method of claim 2, further comprising forming a layer of conductive material over the first mask layer, wherein at least a portion of the conductive material filling the opening.

5. The method of claim 4, further comprising removing the first mask layer and unwanted material comprising the layer of conductive material.

6. The method of claim 1, wherein the second mask layer is an optically reactive dielectric.

7. The method of claim 1, wherein the second mask layer comprises at least one element or compound acting as at least one of a catalyst or an accelerator facilitating converting the second mask layer to the second physical state.

8. The method of claim 1, wherein the second mask layer in the first physical state having high etch resistivity to removal by a wet etch technique.

9. The method of claim 1, wherein the converting of the second mask layer from the first physical state to the second physical state being by exposure of the second mask layer to ultraviolet light.

10. A method for forming a semiconductor device, comprising:
forming a semiconductor stack comprising a plurality of layers including a first mask layer and a second mask layer formed on the first mask layer, wherein the first mask layer comprising an optically reactive layer in a first physical state;
patterning the first mask layer and the second mask layer facilitating forming an opening in the semiconductor stack;
removing the second mask layer exposing the first mask layer in the first physical state; and
converting the first mask layer from the first physical state to a second physical state.

11. The method of claim 10, further comprising removing the first mask layer in the second physical state exposing a layer of interlayer dielectric comprising the semiconductor stack.

12. The method of claim 11, wherein the removing of the first mask layer in the second physical state being by a wet etch technique.

13. The method of claim 11, further comprising forming a layer of conductive material over the interlayer dielectric, wherein at least a portion of the conductive material filling the opening.

14. The method of claim 13, further comprising removing unwanted material comprising the layer of conductive material to form a conductive element comprising the conductive material in the opening.

15. The method of claim 10, wherein the first mask layer is an optically reactive dielectric.

16. The method of claim 10, wherein the first mask layer comprises at least one element or compound acting as at least one of a catalyst or an accelerator facilitating converting the first mask layer to the second physical state.

17. The method of claim 10, wherein the first mask layer in the first physical state having high etch resistivity to removal by a wet etch technique.

18. The method of claim 10, wherein the converting of the second mask layer from the first physical state to the second physical state being by exposure of the second mask layer to ultraviolet light.

19. A semiconductor structure, comprising:
a plurality of layers including a first mask layer, a second mask layer, and a third mask layer, wherein the second mask layer comprising an optically reactive layer which under exposure to ultraviolet light the optically reactive layer is converted from a first physical state to a second physical state; and
an opening through the plurality of layers including the first mask layer, the second mask layer, and the third mask layer.

20. The semiconductor structure of claim 19, wherein the second mask layer comprises at least one element or compound acting as at least one of a catalyst or an accelerator facilitating converting the second mask layer to the second physical state.
